(19) United States
(12) Patent Application Publication
(10) Pub. No.: US 2021/0057612 A1
(43) Pub. Date: Feb. 25, 2021

(54) DISPLAY UNIT AND DISPLAY DEVICE

(71) Applicant: Mitsubishi Electric Corporation, Chiyoda-ku, Tokyo (JP)

(72) Inventor: Yoshinosuke MORI, Tokyo (JP)

(73) Assignee: Mitsubishi Electric Corporation, Chiyoda-ku, Tokyo (JP)

(21) Appl. No.: 16/964,633

(22) PCT Filed: Mar. 28, 2018
(86) PCT No.: PCT/JP2018/012870

§ 371 Date: Jul. 24, 2020

(51) Int. Cl. H01L 33/48; H01L 25/075; H01L 33/58; H01L 33/62

(52) U.S. Cl. CPC H01L 33/486; H01L 33/62; H01L 33/58; H01L 25/0753

(57) ABSTRACT

A display unit includes a case, a circuit board disposed in the case, light emitting elements mounted on the circuit board, and a louver suppressing incidence of external light such as illumination light or sunlight on the circuit board. The case has an opening, and the louver s arranged so as to cover the opening of the case. The louver includes a base end portion that covers the opening of the case, and a first extended portion provided at the base end portion. The first extended portion is configured to extend outward beyond an outer surface of the case.

### TECHNICAL FIELD

The present disclosure relates to a display unit and a display device.

### BACKGROUND ART

A display device includes display units arranged on a support frame in a matrix. The display units are configured by arranging light emitting elements in a matrix and display images such as characters and figures in accordance with input control signals.

In such a display device, a predesigned gap is provided between adjacent display units (for example, refer to Patent Literature 1). Such a gap is provided mainly for improving work efficiency in mounting work or maintenance work.

### CITATION LIST

### Patent Literature

Patent Literature 1: Unexamined Japanese Patent Application Publication No. 2017-187710 (refer to paragraph 0005)

### SUMMARY OF INVENTION

### Technical Problem

Depending on conditions of the environment in which the display device is arranged, foreign matter such as water or dust may enter the inside of the display device through the gap provided between the adjacent display units. If the foreign matter such as water or sand enters the inside of the display device, the foreign matter may cause corrosion or deterioration of components inside the display device.

Also, depending on the environmental conditions in which the display device is arranged, external light such as sunlight or illumination light may enter the inside of the display device through the gap provided between the display units. When the external light enters the inside of the display device, there is a risk that the external light may causes deterioration of the components inside the display device.

Furthermore, the external light that has entered the inside of the display device may be reflected by a support frame that supports the display unit and may exit from the display unit to the outside as reflected light. In this case, light emitted from a light emitting element is immersed in the reflected light, and thus an image displayed on the display unit may be difficult to visually recognize.

In order to solve the aforementioned problem, an objective of the present disclosure is to obtain a display unit and a display device that are capable of suppression of intrusion of foreign matter and entrance of external light into the display device as compared with conventional techniques.

### Solution to Problem

A display unit according to the present disclosure includes a case having an opening, a circuit board disposed in the case, light emitting elements mounted on the circuit board, and a reflection suppressing member that covers the opening of the case. The reflection suppressing member has an extended portion that extends outward from the outer surface of the case.

### Advantageous Effects of Invention

According to the present disclosure, intrusion of foreign matter and entrance of external light into the display device can be suppressed as compared with the conventional techniques.

### BRIEF DESCRIPTION OF DRAWINGS

FIG. 1 is a perspective view of a portion of a structure of a display device according to Embodiment 1 of the present disclosure;

FIG. 2 is a front view of a display unit according to Embodiment 1 of the present disclosure;

FIG. 3A is a cross-sectional view taken along a line A-A in FIG. 2;

FIG. 3B is a cross-sectional view taken along a line B-B in FIG. 2;

FIG. 4 is a top view of a portion of the display device according to Embodiment 1 of the present disclosure;

FIG. 5 is a top view illustrating an enlarged image of an area indicated by a dashed-line frame in FIG. 4;

FIG. 6 is a partial enlarged front view illustrating an enlarged image of a portion of the display device according to Embodiment 1 of the present disclosure;

FIG. 7 is a front view of a display unit according to Embodiment 2 of the present disclosure;

FIG. 8 is a cross-sectional view taken along a line D-D in FIG. 7;

FIG. 9 is a top view of a portion of a display device according to Embodiment 2 of the present disclosure;

FIG. 10 is a top view illustrating an enlarged image of an area indicated by a dashed-line frame in FIG. 9;

FIG. 11 is a partial enlarged front view illustrating an enlarged image of a portion of the display device according to Embodiment 2 of the present disclosure;

FIG. 12 is a front view of a display unit according to Embodiment 3 of the present disclosure;

FIG. 13 is a partial enlarged front view illustrating an enlarged image of a portion of a display device according to Embodiment 3 of the present disclosure;

FIG. 14A is a perspective view of a conventional display device;

FIG. 14B is a perspective view of a conventional display device;

FIG. 15 is a front view of a display unit according to Embodiment 4 of the present disclosure;

FIG. 16 is a partial enlarged front view illustrating an enlarged image of a portion of a display device according to Embodiment 4 of the present disclosure;

FIG. 17 is a front view of a display unit according to another embodiment of the present disclosure;

FIG. 18 is a partial enlarged front view illustrating an enlarged image of a portion of a display device according to the other embodiment of the present disclosure;

FIG. 19 is a partial enlarged front view illustrating an enlarged image of a portion of a display device according to yet another embodiment of the present disclosure; and

FIG. 20 is a partial enlarged front view illustrating an enlarged image of a portion of a display device according to yet another embodiment of the present disclosure.

### DESCRIPTION OF EMBODIMENTS

Embodiments of the present disclosure are described with reference to attached drawings. Components that are the same or equivalent are assigned the same reference signs throughout the drawings. Duplicate descriptions are appropriately abbreviated or omitted. Also, for illustrative purposes, each of the drawings may illustrate a component such that the proportion of the size or shape of the component is exaggerated.

### Embodiment 1

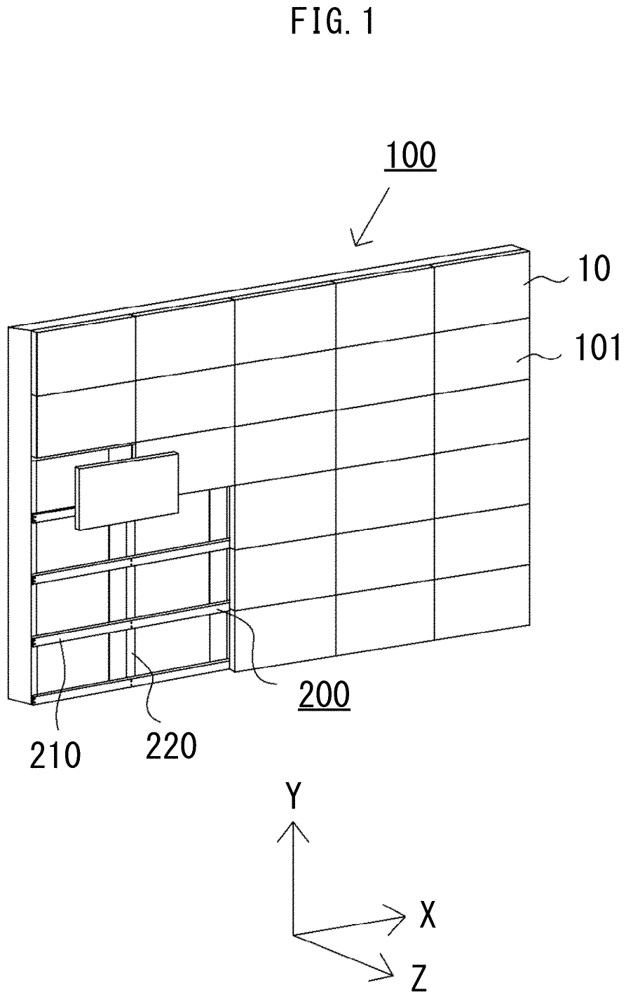

Display units 10 and a display device 100 according to Embodiment 1 of the present disclosure are described with reference to FIGS. 1 to 6.

As illustrated in FIG. 1, the display device 100 according to Embodiment 1 is configured to include the display units 10 that display an image and that are arranged in a matrix. Surfaces of the display units 10 and the display device 100 on which the image are displayed are referred to as a display surface 101.

The display units 10 are attached to a support frame 200. In order to clearly illustrate the support frame 200, only some of the display units 10 are illustrated in FIG. 1. The display device 100 is installed outdoors, for example, in a stadium or indoors, for example, in a gymnasium.

A case in which the display device 100 and the display units 10 are installed perpendicularly to the ground is described below. When the display surface 101 is viewed from the front, the horizontal direction is taken to be the X-axis direction, the direction perpendicular to the ground is taken to be the Y-axis direction, and the direction perpendicular to the X-axis direction and the Y-axis direction is taken to be the Z-axis direction. Additionally, when the display surface 101 is viewed from the front, the right direction is taken to be the X-axis positive direction, the left direction is taken to be the X axis negative direction, the upward direction is taken to be the Y-axis positive direction, and the downward direction is taken to be the Y axis negative direction. Regarding the Z-axis direction, the direction from the back side of the display surface 101 to the front side of the display surface 101 is taken to be the Z-axis positive direction, and the opposite direction to the Z-axis positive direction that is the direction from the front side to the display surface 101 is taken to be the Z-axis negative direction. The definitions of these directions of the axes are the same as those in other embodiments.

The support frame 200 is made of a metal material such as aluminum or copper and includes beams 210 extending in parallel with the X axis and columns 220 extending in parallel with the Y axis. That is, the support frame 200 includes the beams 210 and the columns 220 connected in a lattice shape. The display device 100 is configured by attaching the display units 10 to the support frame 200 configured as described above.

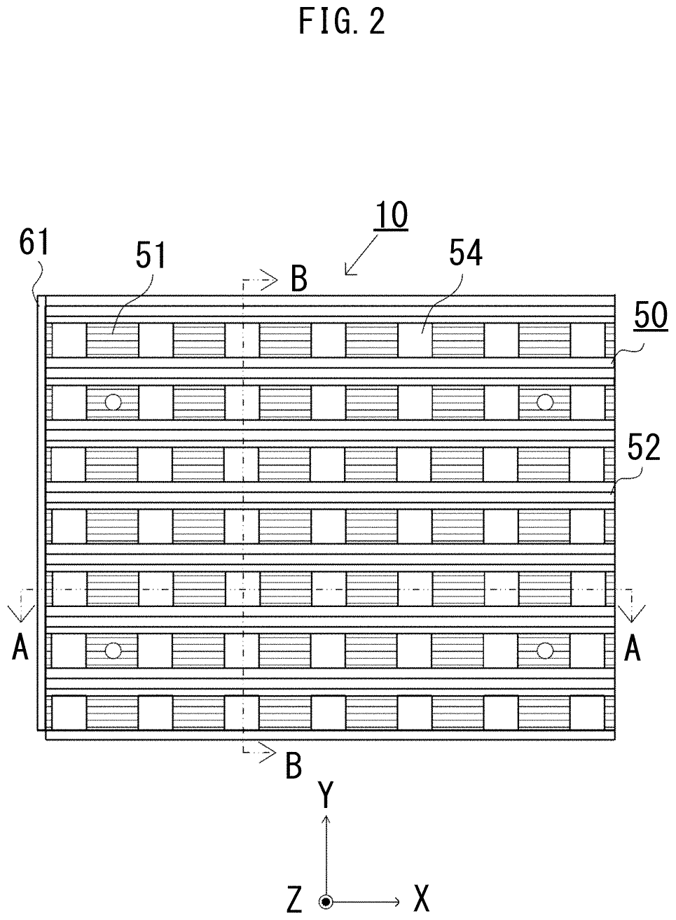

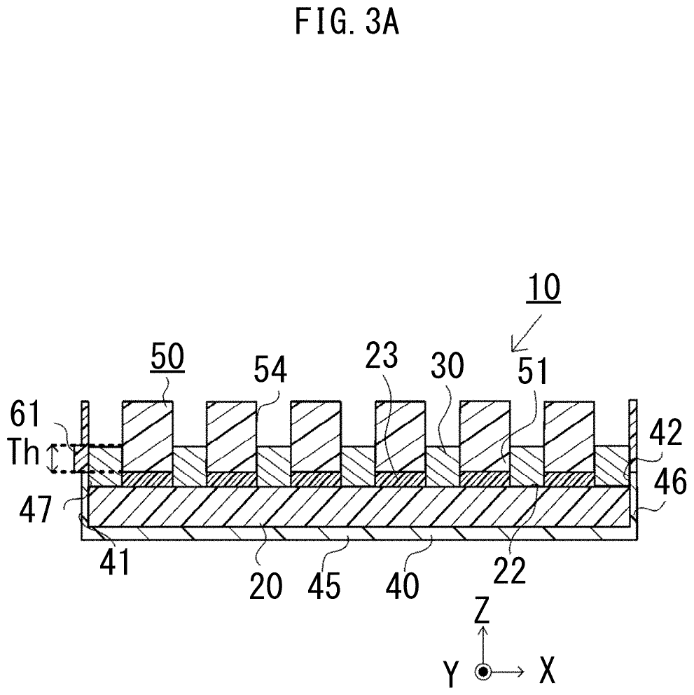

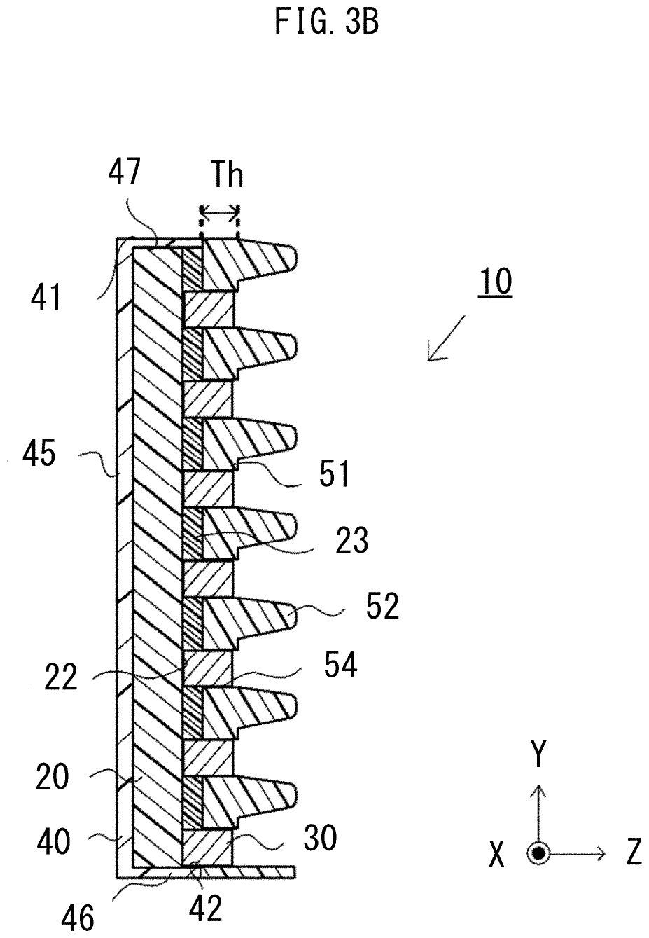

FIG. 2 is a front view of the display unit 10 according to Embodiment 1 when viewed in the Z-axis negative direction. FIG. 3A is a cross-sectional view taken along a line A-A in FIG. 2, and FIG. 3B is a cross-sectional view taken along a line B-B in FIG. 2.

As illustrated in FIGS. 2, 3A and 3B, the display unit 10 includes a case 40, a circuit board 20 disposed in the case 40, and light emitting elements 30 that are mounted on a mounting surface 22 of the circuit board 20. An image is displayed by the whole of the light emitting elements 30, and each of the light emitting elements 30 serves as a pixel forming the image.

The circuit board 20 is made of an insulating resin material, glass material, ceramic material or the like, and non-illustrated wiring for supplying power to the light emitting elements 30 is provided on the mounting surface 22. Also, the mounting surface 22 of the circuit board 20 is provided with a non-illustrated driving integrated circuit (IC) that drives the light emitting elements 30.

The light emitting elements 30 are 3-in-1 surface-mount LED elements and are arranged on the mounting surface 22 of the circuit board 20, for example, in seven columns and seven rows. The light emitting elements 30 emit light of a freely selected color with a freely selected intensity by electric power supplied from the driving IC of the circuit board 20. As a result, a color image is displayed on the display unit 10 by the light emitting elements 30.

The case 40 is a housing that has an opening 42 that opens in the positive Z-axis direction and that includes (i) a bottom 45 along the plane including the X axis and the Y axis, (ii) a side wall 46 along the plane including the Y axis and the Z axis, and (iii) a side wall 46 along the plane including the X axis and the Z axis. The case 40 is made of a resin material such as polycarbonate resin or acrylic resin. Also, in the case 40, a surface on which the circuit board 20 is disposed is referred to as an inner surface 47, and a surface exposed to the outside of the case 40 is referred to as an outer surface 41.

The circuit board 20 on which the light emitting elements 30 are mounted is arranged in the case 40 with the mounting surface 22 facing the positive direction of the Z axis. The mounting surface 22 is covered with a filler 23 for waterproof protection. The filler 23 is made of water-repellant epoxy resin or the like.

Also, the case 40 is provided with a louver 50 (corresponding to the “reflection suppressing member” in the claims). As described above, since the wiring is provided on the circuit board 20, when external light enters the circuit board 20, the external light is reflected by the wiring and thus is visually recognized as reflected light. The louver 50 suppresses the generation of reflected light by blocking the external light from entering the circuit board 20.

The louver 50 is preferably made of black resin by injection molding. Furthermore, in order to efficiently suppress reflection of external light such as sunlight or illumination light, a surface of the louver is preferably subjected to embossing as illustrated in FIG. 2.

The louver 50 includes (i) a base end portion 51 that covers the side walls 46 and the opening 42 of the case 40 in the Z-axis negative direction, (ii) an eaves portion 52 that protrudes, like eaves, from the base end portion 51 in the Z-axis positive direction, and (iii) a first extended portion 61 provided at an end of the base end portion 51 in the X-axis negative direction. Although an example in which the first extended portion 61 is provided at the end of the base end portion 51 in the X-axis negative direction is described in Embodiment 1, the first extended portion 61 may be provided at an end of the base end portion 51 in the X-axis positive direction.

The base end portion 51 is formed in a flat plate shape having a thickness Th in the Z-axis direction. The base end portion 51 is provided with openings 54 that correspond to positions where the light emitting elements 30 are disposed.

The first extended portion 61 is provided at the end of the base end portion 51 in the X-axis negative direction and extends outward from the outer surface 41 of the case 40. Also, as illustrated in FIG. 2, the first extended portion 61 extends continuously from an end portion of the base end portion 51 in the Y-axis positive direction to an end portion in the Y-axis negative direction. In Embodiment 1, an example is described in which the thickness Th of the base end portion 51 in the Z-axis direction is the same as the thickness of the first extended portion 61 in the Z-axis direction. However, the thickness Th of the base end portion 51 in the Z-axis direction may be different from the thickness of the first extended portion 61 in the Z-axis direction.

Although the first extended portion 61 is preferably formed integrally with the base end portion 51 by injection molding, the first extended portion 61 may be added to the base end portion 51 after manufacturing the first extended portion 61 from a material different from the material of the base end portion 51. Also, although the first extended portion 61 is preferably made of black resin that has the same color as the base end portion 51 so that the reflectance of external light such as sunlight may become low, the first extended portion 61 may be made of resin having a different color from the color of the base end portion 51. Also, embossing may be performed on the surface of the first extended portion 61.

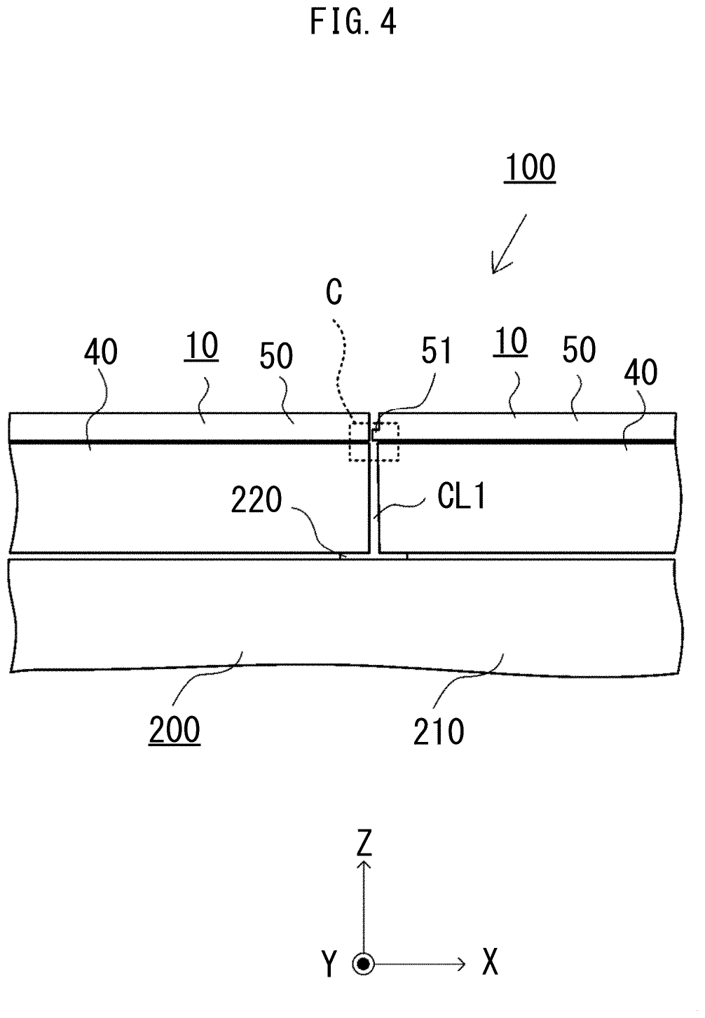

FIG. 4 illustrates a portion of the top view of the display device 100 according to Embodiment 1 when viewed from the Y axis positive direction. As illustrated in FIG. 4, two adjacent display units 10 are arranged with a pre-designed gap CL1 therebetween. In other words, the pre-designed gap CL1 is provided between the two display units 10 for the purpose of improving efficiency of attachment work and maintenance work.

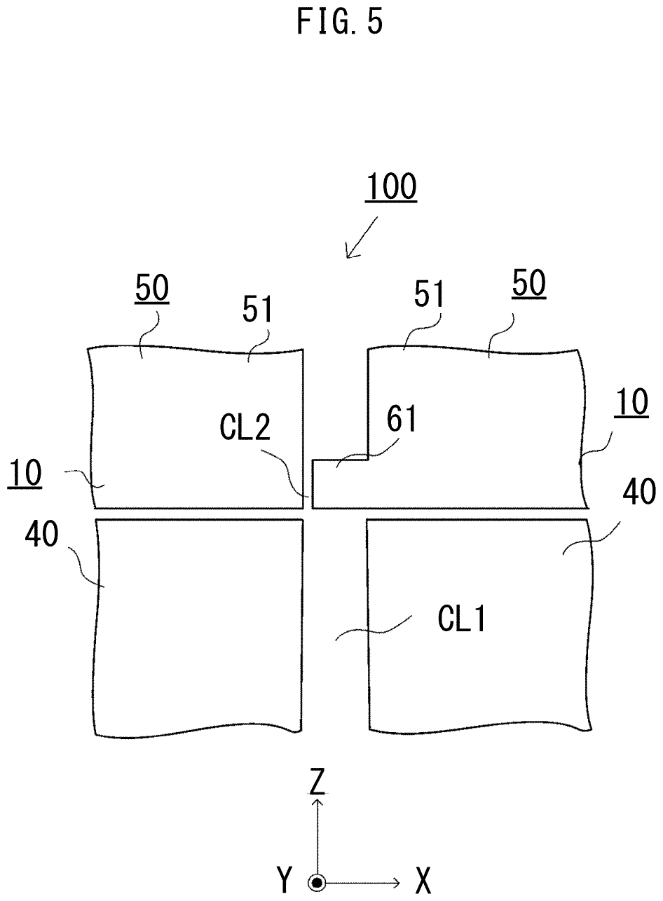

FIG. 5 is an enlarged top view in which the area indicated by the dashed-line frame C in FIG. 4 is enlarged. The two display units 10 illustrated in FIG. 5 are arranged to be adjacent to each other such that a louver 50 included in one of the two display units 10 and a louver 50 included in the other of the two display units 10 face each other in the X-axis direction.

Also, the two louvers 50 are arranged adjacent to each other such that the first extended portion 61 included in one of the two louvers 50 and the base end portion 51 included in the other of the two louvers 50 face each other in the X-axis direction.

As a result of such arrangement, the first extended portion 61 included in one of the two louvers 50 covers at least a portion of the gap CL1 in the Z-axis negative direction.

Also, as illustrated in FIG. 5, a gap CL2 is provided between the first extended portion 61 included in one of the two adjacent louvers 50 and the base end portion 51 included in the other of the two adjacent louvers 50.

Depending on conditions of the environment where the display device 100 is installed, the louvers 50 included in the respective display units 10 may thermally expand. When such thermal expansion occurs, the first extending portion 61 included in one of the louvers 50 and the base end portion 51 included in the other of the louvers 50 may come into contact with each other and thus may be damaged. In this regard, according to Embodiment 1, since the first extended portion 61 included in one of the two adjacent louvers 50 and the base end portion 51 included in the other of the two adjacent louvers 50 are spaced away from each other by the gap CL2, contact between these louvers 50 can be suppressed even when the louvers 50 thermally expand.

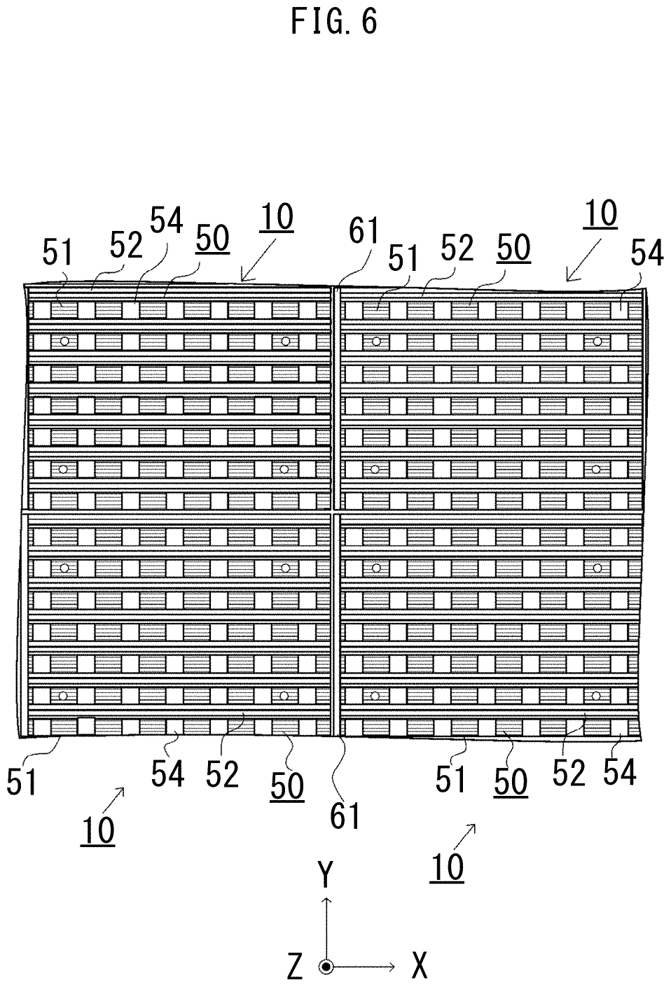

FIG. 6 is a partial enlarged front view of a portion of the display device 100 illustrated in FIG. 1 in which four freely-selected display units 10 are arranged in a matrix when viewed in the Z-axis negative direction.

As illustrated in FIG. 6, the first extended portion 61 is provided at the end of the base end portion 51 in the X-axis negative direction and continuously extends from an end of the base end portion 51 in the Y-axis positive direction to an end of the base end portion 51 in the Y-axis negative direction. As a result, the gap CL1 provided between the adjacent display units 10 is at least partially covered by the first extended portion 61 over the range from the end in the Y-axis positive direction to the end in the Y-axis negative direction.

According to Embodiment 1 described above, the following effects can be achieved.

(1) According to Embodiment 1, since at least a portion of the gap CL1 extending in the Y-axis direction can be covered by the first extended portion 61, the intrusion of foreign matter into the display device 100 through the gap CL1 and the entrance of external light into the display device 100 through the gap CL1 can be suppressed as compared with the conventional techniques. As a result, the deterioration of components inside the display device 100 due to the intrusion of foreign matter or the entrance of external light can be suppressed as compared with the conventional techniques.

(2) Since the support frame 200 is made of metal material, the support frame 200 easily reflects external light. As a result, when external light that has entered the display device 100 through the gap CL1 made between adjacent display units 10 reaches the support frame 200, the external light is reflected by the support frame 200 and exits the display device 100 as reflected light. In this regard, according to Embodiment 1, the entrance of external light through the gap CL1 can be suppressed as compared with the conventional techniques, and thus the generation of reflected light can be suppressed as compared with the conventional techniques.

(3) In Embodiment 1, the two adjacent louvers 50 are arranged spaced away from each other by the gap CL 2 between the first extended portion 61 included in one of the two adjacent louvers 50 and the base end portion 51 included in the other of the two adjacent louvers 50. As a result, even if the louvers 50 thermally expand, contact between the first extended portion 61 included in one of the two adjacent louvers 50 and the base end portion 51 included in the other of the two adjacent louvers 50 can be suppressed. Thus, the damage due to thermal expansion can be suppressed.

### Embodiment 2

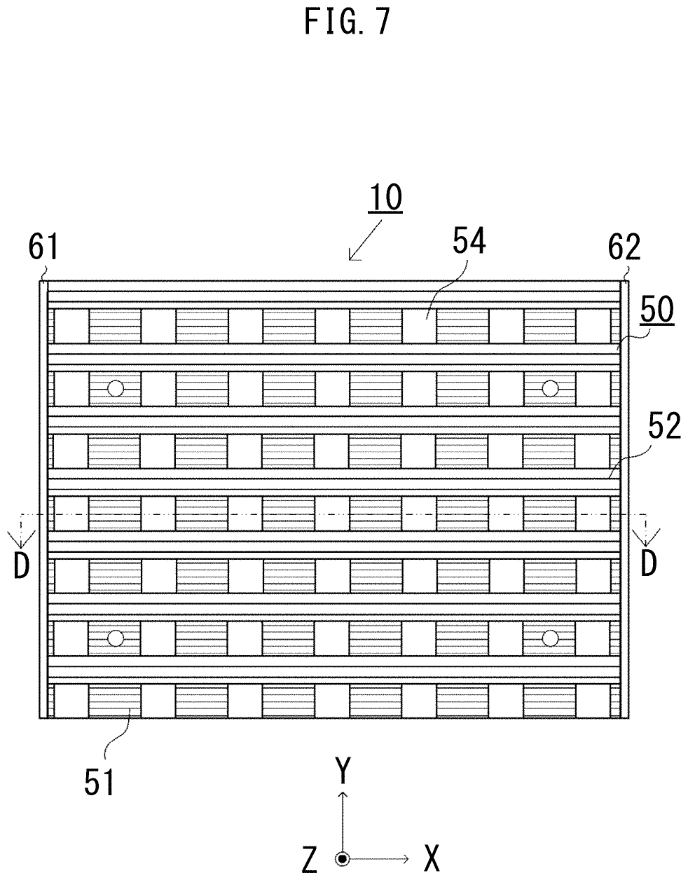

A display unit 10 and a display device 100 according to Embodiment 2 are described with reference to FIGS. 7 to 11 in addition to FIG. 1. Unless otherwise noted, components that are the same are assigned the same reference signs, and detailed descriptions thereof are omitted as appropriate.

As illustrated in FIG. 7, each of the louvers 50 included in the display unit 10 according to Embodiment 2 includes (i) the first extended portion 61 provided at the end of the base end portion 51 in the X-axis negative direction, and (ii) a second extended portion 62 provided at the end of the base end portion 51 in the X-axis positive direction. Both the first extended portion 61 and the second extended portion 62 continuously extend from the end of the base end portion 51 in the Y-axis positive direction to the end of the base end portion 51 in the Y-axis negative direction.

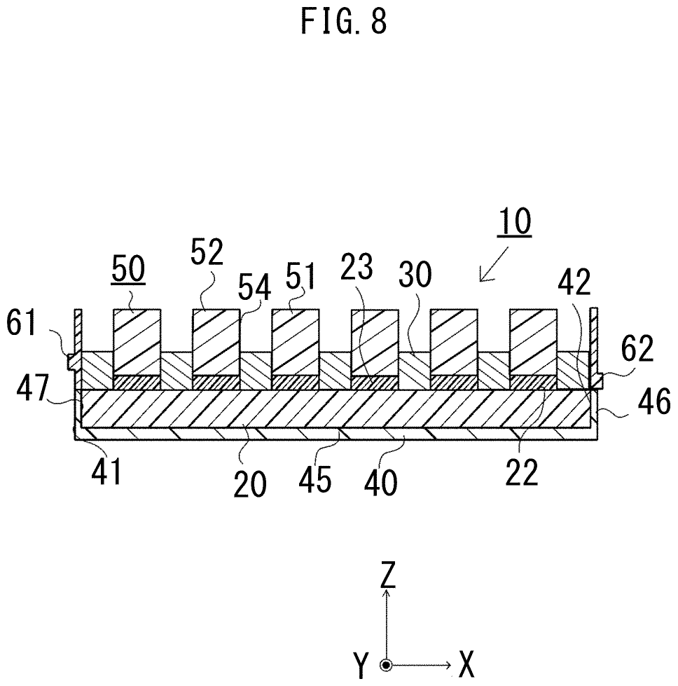

FIG. 8 is a cross-sectional view taken along the line D-D in FIG. 7. As illustrated in FIG. 8, the first extended portion 61 is provided at the end of the base end portion 51 in the X-axis negative direction, and the second extended portion 62 is provided at the end of the base end portion 51 in the X-axis positive direction. Also, the first extended portion 61 and the second extended portion 62 are provided at different positions in the Z-axis direction corresponding to the “thickness direction of the base end portion” in the claims. That is, the first extended portion 61 and the second extended portion 62 are provided at positions at which the first and second extended portions do not overlap each other in the Z-axis direction.

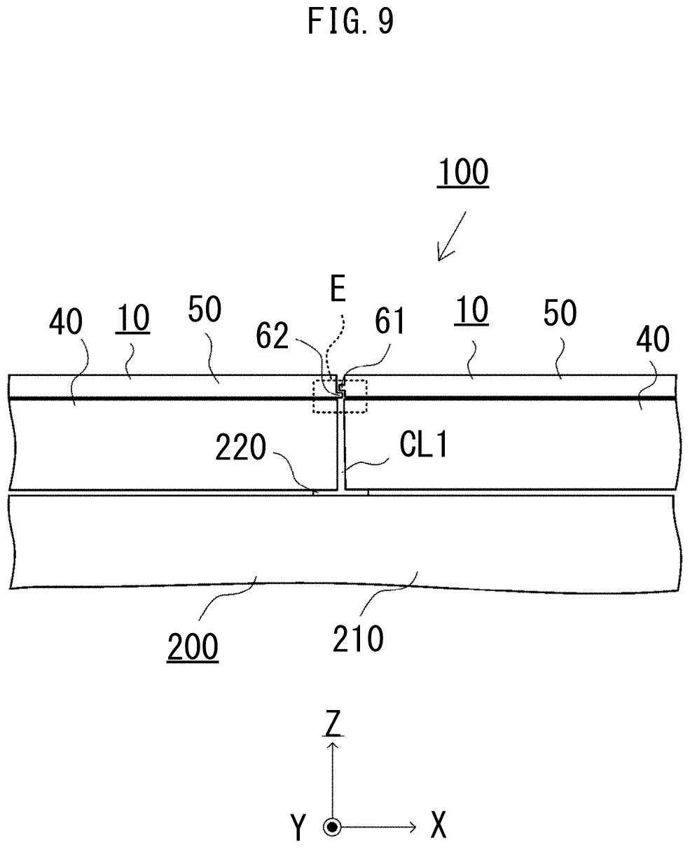

FIG. 9 illustrates a portion of a top view of the display device 100 according to Embodiment 2 of the present disclosure when viewed from the Y axis positive direction. As illustrated in FIG. 9, two adjacent display units 10 are arranged to be spaced apart by the gap CL1 designed in advance.

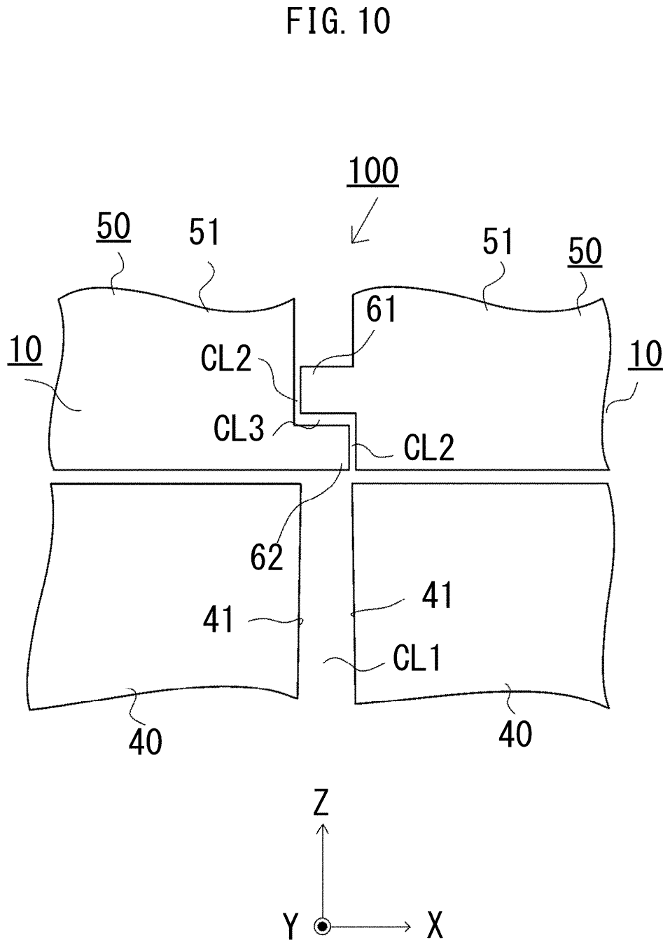

FIG. 10 illustrates an enlarged top view in which the area indicated by the dashed-line frame E in FIG. 9 is enlarged. As illustrated in FIG. 10, two adjacent display units 10 are arranged such that a louver 50 included in one of the two adjacent display unit 10 and a louver 50 included in the other of the two adjacent display units 10 face each other in the X-axis direction and the Z-axis direction.

Specifically, the two louvers 50 adjacent to each other are arranged such that the first extended portion 61 included in one of the two louvers 50 faces the base end portion 51 included in the other of the two louvers 50 in the X-axis direction. Also, the two louvers 50 adjacent to each other are arranged such that the first extended portion 61 included in one of the two louvers 50 faces the second extended portion 62 included in the other of the two louvers 50 in the Z-axis direction.

Additionally, the two louvers 50 adjacent to each other are arranged such that the second extended portion 62 included in one of the two louvers 50 faces the base end portion 51 included in the other of the two louvers 50 in the X-axis direction.

By such arrangement, the gap CL1 is covered, in the Z-axis negative direction, by the first extended portion 61 and the second extended portion 62.

Also, in Embodiment 2, the two louvers 50 adjacent to each other are arranged such that the first extended portion 61 included in one of the two louvers 50 and the second extended portion 62 included in the other of the two louvers 50 face each other in the Z-axis direction with the gap CL3 therebetween. Also, the two louvers 50 adjacent to each other are arranged such that the first extended portion 61 included in one of the two louvers 50 and the base end portion 51 included in the other of the two louvers 50 face each other in the X-axis direction with the gap CL2 therebetween. Additionally, the two louvers 50 adjacent to each other are arranged such that the second extended portion 62 included in one of the two louvers 50 and the base end portion 51 included in the other of the two louvers 50 face each other in the X-axis direction with the gap CL2 therebetween.

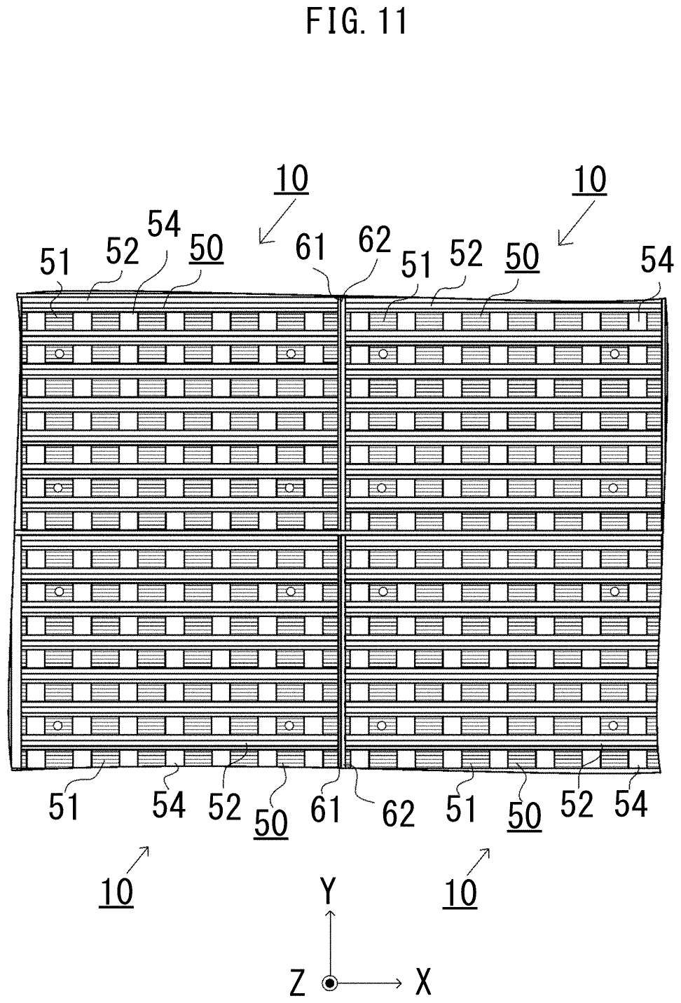

FIG. 11 is a partial enlarged front view of a portion where arbitrary four display units 10 according to Embodiment 2 are arranged in a matrix in the display device 100 illustrated in FIG. 1, when viewed in the Z-axis negative direction.

As described above, the first extended portion 61 and the second extended portion 62 continuously extend from the end of the base end portion 51 in the Y-axis positive direction to the end of the base end portion 51 in the Y-axis negative direction. As a result, the gap CL1 extending in the Y-axis direction is covered by the first extended portion 61 and the second extended portion 62 over the range from the end of the base end portion 51 in the Y-axis positive direction to the end of the base end portion 51 in the Y-axis negative direction.

According to Embodiment 2 described above, in addition to the effects (1) to (3) described in Embodiment 1, the following effects can be achieved.

(4) In Embodiment 2, the first extended portion 61 and the second extended portion 62 are provided on two opposite sides of the base end portion 51 and at different positions in the thickness direction of the base end portion 51. Accordingly, the first expansion portion 61 and the second expansion portion 62 can be arranged so as to face each other in the Z-axis direction. As a result, the gap CL1 extending in the Y-axis direction can be covered by both the first extended portion 61 and the second extended portion 62. Thus, the intrusion of foreign matter or the entrance of sunlight into the gap CL1 can be suppressed more effectively as compared with the conventional techniques.

(5) In Embodiment 2, the first extended portion 61 and the second extended portion 62 face each other with the gap CL3 therebetween in the Z-axis direction. Also, the first extended portion 61 faces the base end portion 51 of the adjacent louver 50 with the gap CL2 therebetween in the X-axis direction. Similarly, the second extended portion 62 also faces the base end portion 51 of the adjacent louver 50 with the gap CL2 therebetween in the X-axis direction. As a result, even in a case in which the louvers 50 thermally expand, contact between the first extended portion 61 and the second extended portion 62 can be suppressed. Also, contacts between the first extended portion 61 or the second extended portion 62 and the base end portion 51 of the adjacent louver 50 can be suppressed. Thus, occurrence of breakage due to thermal expansion can be suppressed.

### Embodiment 3

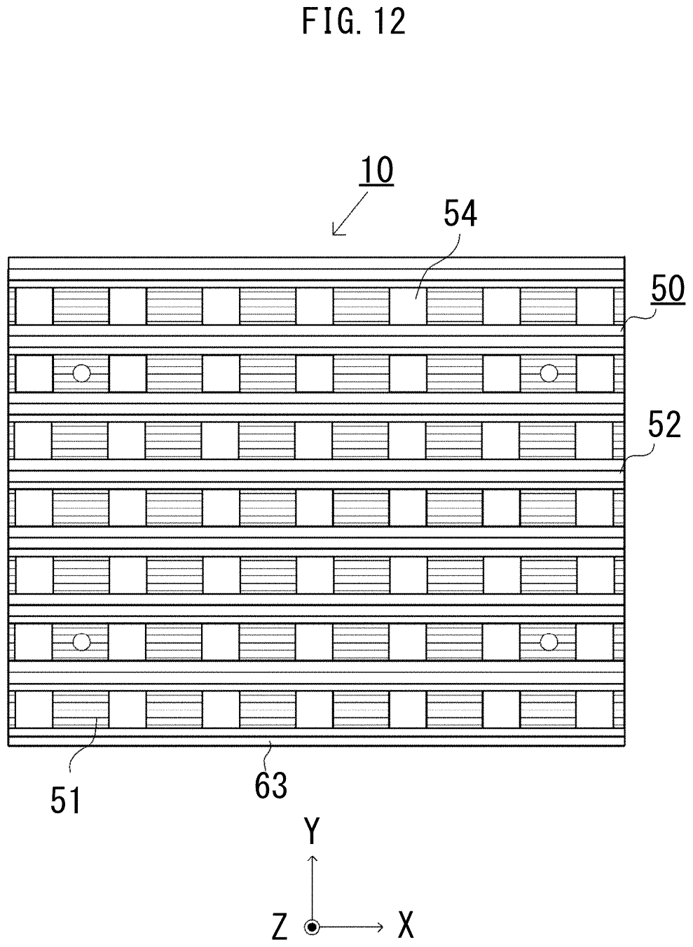

A display unit 10 and a display device 100 according to Embodiment 3 are described with reference to FIGS. 12 to 14 in addition to FIG. 1. Unless otherwise noted, components that are the same are assigned the same reference signs, and detailed descriptions thereof are omitted as appropriate.

As illustrated in FIG. 12, in the display unit 10 according to Embodiment 3, the louver 50 includes a third extended portion 63 provided at the end of the base end portion 51 in the Y-axis negative direction. The third extended portion 63 extends continuously from the end in the X-axis negative direction to the end in the X-axis positive direction.

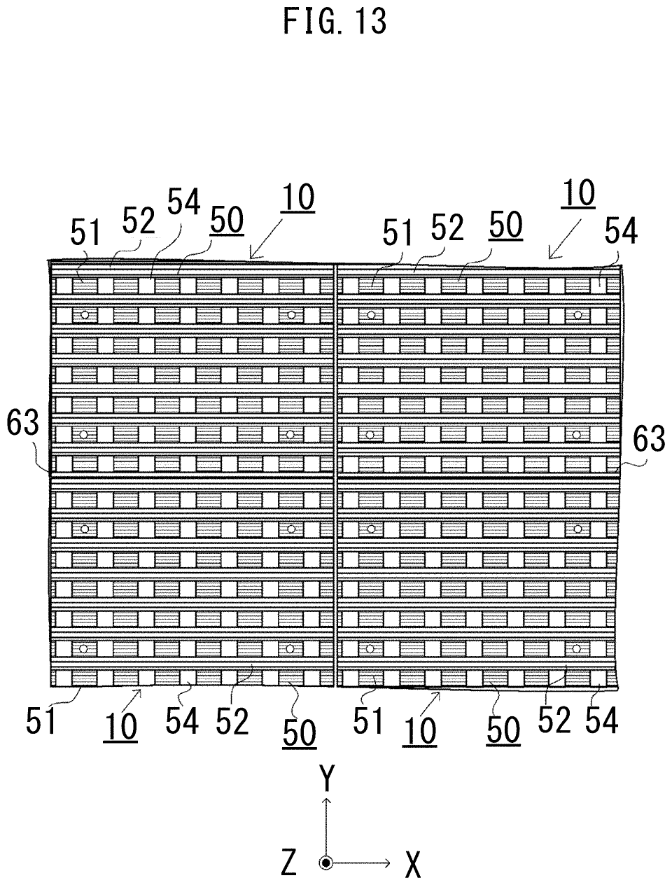

FIG. 13 is a partial enlarged front view of a portion where arbitrary four display units 10 according to Embodiment 3 are arranged in a matrix in the display device 100 illustrated in FIG. 1, when viewed in the Z-axis negative direction.

As illustrated in FIG. 13, in Embodiment 3, the third extended portion 63 is attached to the support frame 200 so as to be positioned in the Y axis negative direction of the base end portion 51. That is, in Embodiment 3, the third extended portion 63 is disposed to be positioned below the base end portion 51 in the vertical direction. Also, as described above, the third extended portion 63 continuously extends from the end of the base end portion 51 in the X-axis positive direction to the end of the base end portion 51 in the X-axis negative direction.

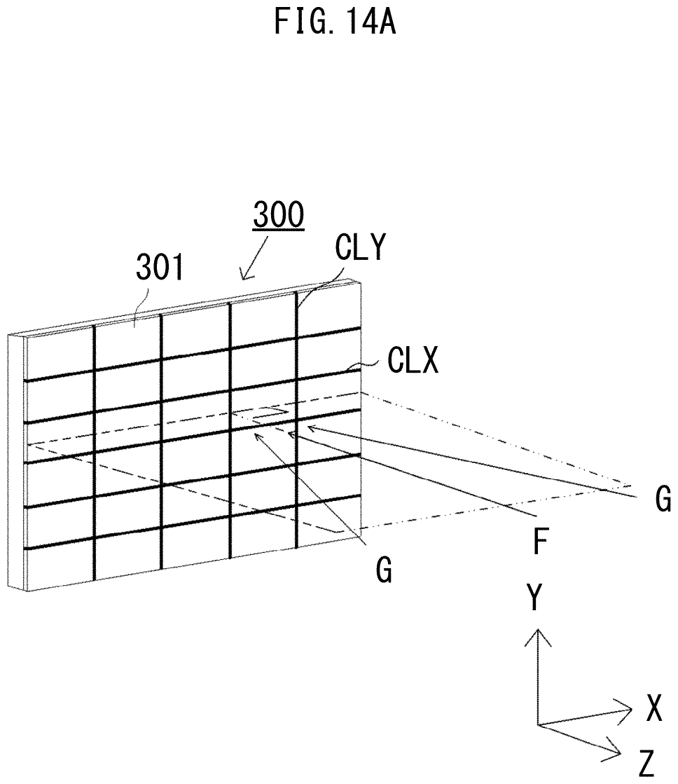

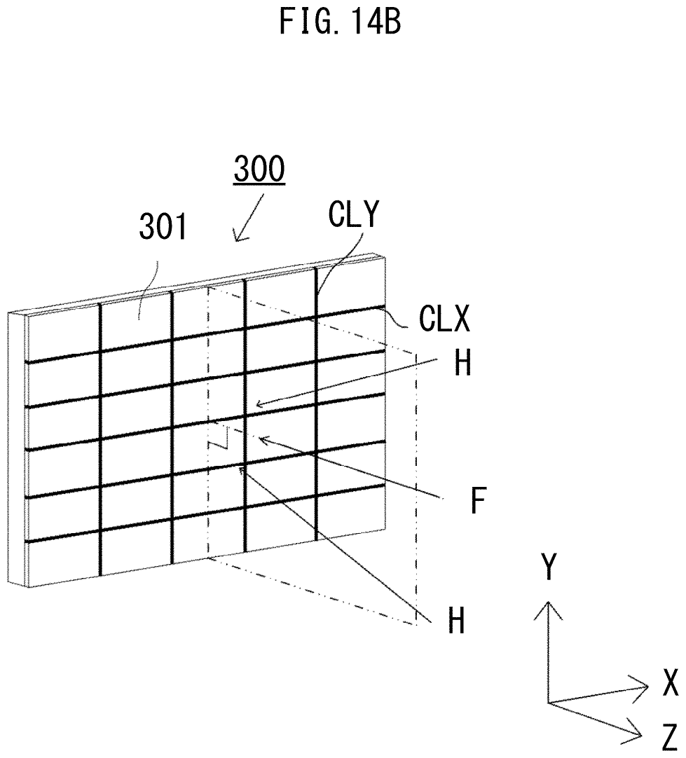

FIGS. 14A and 14B are explanatory perspective views of a conventional display device 300 configured by arranging conventional display units 301 in a matrix. As illustrated in FIGS. 14A and 14B, in the conventional display device 300, a gap CLX extending in the X-axis direction and a gap CLY extending in the Y-axis direction are provided between adjacent display units 301.

As indicated by an arrow F in FIG. 14A, when the display device 300 is viewed in the Z-axis negative direction, both the gap CLX and the gap CLY can be visually recognized. However, as indicated by an arrow G, when the display device 301 is viewed from a position shifted in the X-axis direction, the gap CLY extending in the Y-axis direction becomes more difficult to visually recognize than a case in which the display device 300 is visually recognized in the Z-axis negative direction. This is because the gap CLY is shielded by the louver 50. However, the gap CLX extending in the X-axis direction is not shielded by the louver 50 and the gap CLX can be visually recognized even from a position shifted in the X-axis direction.

Similarly, as indicated by an arrow H in FIG. 14B, when the display device 300 is viewed from a position shifted in the Y-axis direction, the gap CLX extending in the X-axis direction becomes more difficult to visually recognize than a case in which the display device 300 is visually recognized in the Z-axis negative direction. This is because the gap CLX is shielded by the louver 50. However, the gap CLY extending in the Y-axis direction is not shielded by the louver 50 and thus can be easily visually recognized even from a position shifted in the Y-axis direction.

Generally, the display device 300 is more often viewed from a position shifted in the X-axis direction than viewed from a position shifted in the Y-axis direction. Accordingly, the gap CLX extending in the X-axis direction is likely to be visually recognized by more viewers than the gap CLY extending in the Y-axis direction. That is, when external light enters the inside of the display device 300 and exits, as reflected light, to the outside through the gap CLX or the gap CLY, reflected light exiting to the outside through the gap CLX is likely to be visually recognized by more viewers than reflected light exiting to the outside through the gap CLY.

In this regard, according to Embodiment 3, since the third extended portion 63 is provided at the end in the Y-axis negative direction, at least a portion of the gap corresponding to the gap CLX is covered in the Z-axis negative direction. In other words, the third extended portion 63 covers, in the Z-axis negative direction, at least a portion of a gap CL1 extending in the X-axis direction, among the gaps CL1 provided in the display device 100 according to Embodiment 3. Thus, the possibility that the reflected light is visually recognized can be more advantageously reduced.

According to Embodiment 3 described above, in addition to the effects (1) to (5) described in Embodiments 1 and 2, the following effect can be achieved.

(6) According to Embodiment 3, since the third extended portion 63 is arranged at the end of the base end portion 51 in the Y-axis negative direction, the possibility that the reflected light is visually recognized is more advantageously reduced.

### Embodiment 4

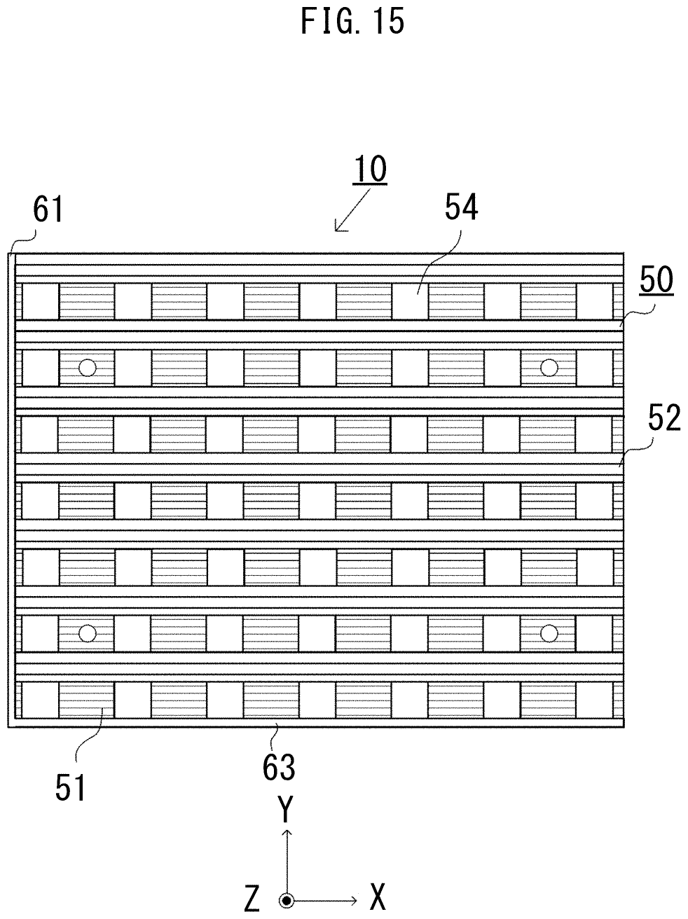

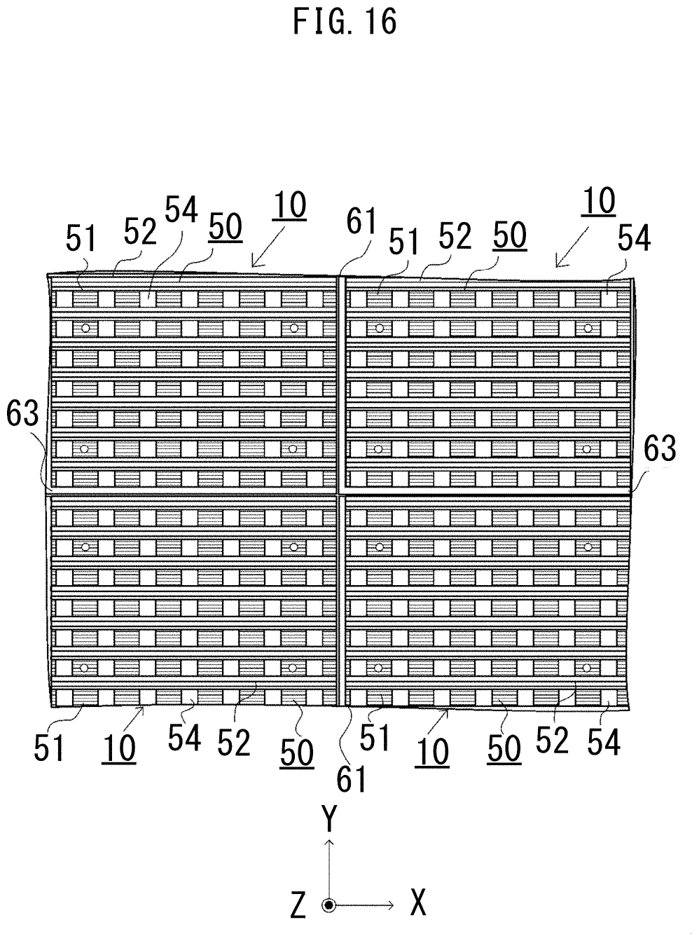

A display unit 10 and a display device 100 according to Embodiment 4 are described with reference to FIGS. 15 to 16 in addition to FIG. 1. Unless otherwise noted, components that are the same are assigned the same reference signs, and detailed descriptions thereof are omitted as appropriate.

As illustrated in FIG. 15, the louver 50 included in a display unit 10 according to Embodiment 4 includes (i) the first extended portion 61 provided at the end in the X-axis negative direction and (ii) the third extended portion 63 provided at the end in the Y-axis negative direction. The first extended portion 61 continuously extends from the end of the base end portion 51 in the Y-axis negative direction to the end of the base end portion 51 in the Y-axis positive direction, and the third extended portion 63 continuously extends from the end of the base end portion 51 in the X-axis negative axis direction to the end of the base end portion 51 in the X-axis positive direction.

FIG. 16 is a partial enlarged front view of a portion where arbitrary four display units 10 according to Embodiment 4 are arranged in a matrix in the display device 100 illustrated in FIG. 1, when viewed in the Z-axis negative direction.

As described above, the first extended portion 61 continuously extends from the end of the base end portion 51 in the Y-axis positive direction to the end of the base end portion 51 in the Y-axis negative direction, and the third extended portion 63 continuously extends from the end of the base end portion 51 in the X-axis positive direction to the end of the base end portion 51 in the X-axis negative direction. As a result, among the gaps CL1 between the adjacent display units 10, at least portions of a gap CL1 extending in the X-axis direction and a gap CL1 extending in the Y-axis direction are to be covered in the Z-axis negative direction.

According to Embodiment 4 described above, in addition to the effects (1) to (6) described in Embodiments 1 to 3, the following effect can be achieved.

(7) According to Embodiment 4, at least portions of the gap CL1 extending in the X-axis direction and the gap CL1 extending in the Y-axis direction are covered, in the Z-axis negative direction, by the first extending portion 61 and the third extending portion 63. As a result, the intrusion of foreign matter and the entrance of external light into the display device 100 can be more advantageously suppressed as compared with the conventional techniques.

### Other Embodiments

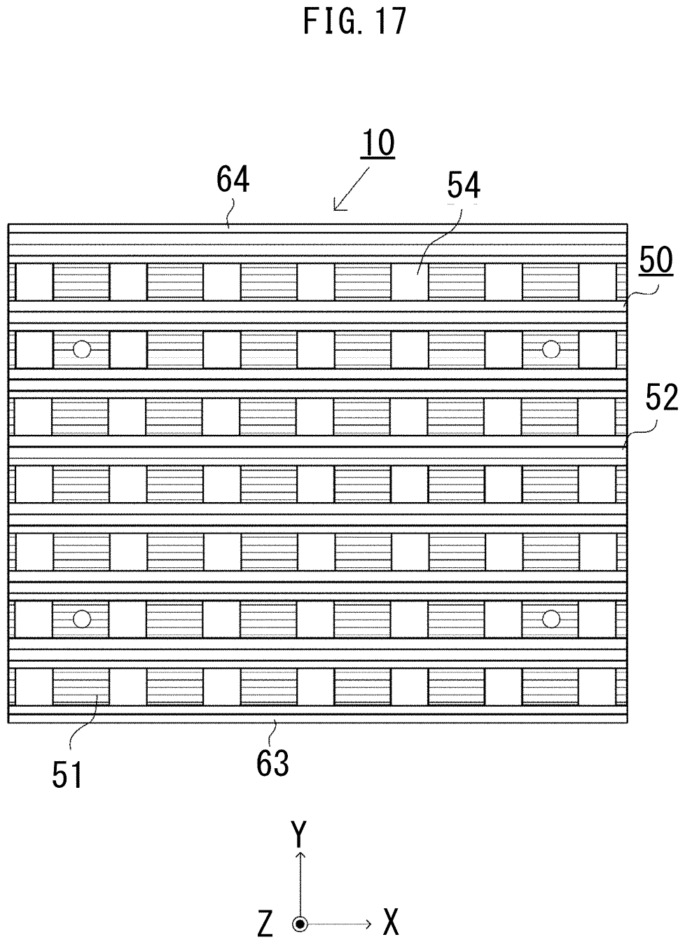

In Embodiment 3, the third extended portion 63 is provided at the end in the Y-axis negative direction. However, the present disclosure is not limited to this, and as illustrated in FIG. 17, a fourth extended portion 64 may be provided at the end in the Y-axis positive direction.

In the above-described modified example, the third extended portion 63 provided at the end in the Y-axis negative direction and the fourth extended portion 64 provided at the end in the Y-axis positive are preferably provided at positions at which the third and fourth extended portions do not overlap each other in the Z-axis direction. Also, when the display units 10 according to the present modified example are attached to the display device 100, a gap CL2 is preferably provided between (i) the third expansion portion 63 or the fourth expansion portion 64 and (ii) the base end portion 51 included in the adjacent louver 50.

Although the louver 50 is provided with the third extended portion 63 and the fourth extended portion 64 in the above-described modified example, the third extended portion 63 may be omitted. That is, the third extended portion 63 provided below the base end portion 51 in the vertical direction may be omitted, and the fourth extended portion 64 may be provided above the base end portion 51 in the vertical direction.

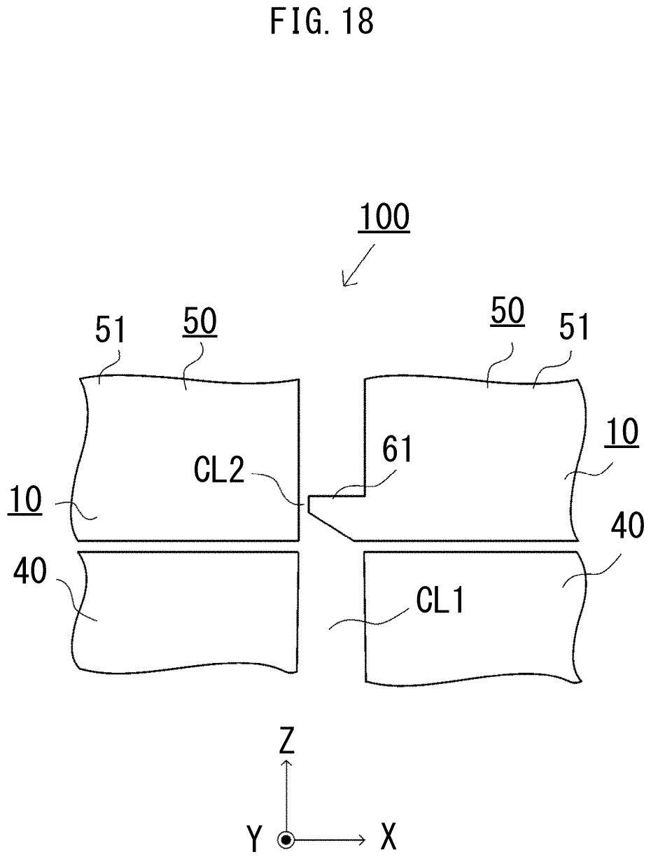

As illustrated in FIG. 18, the first expansion portion 61 described in Embodiment 1 may have a tapered shape that narrows with increase in distance from the base end portion 51. Also, although not illustrated, the second extended portion 62, the third extended portion 63, or the fourth extended portion 64 described in each of the above-described embodiments or the above-described modified example may have a tapered shape that narrows with increase in distance from the base end portion 51.

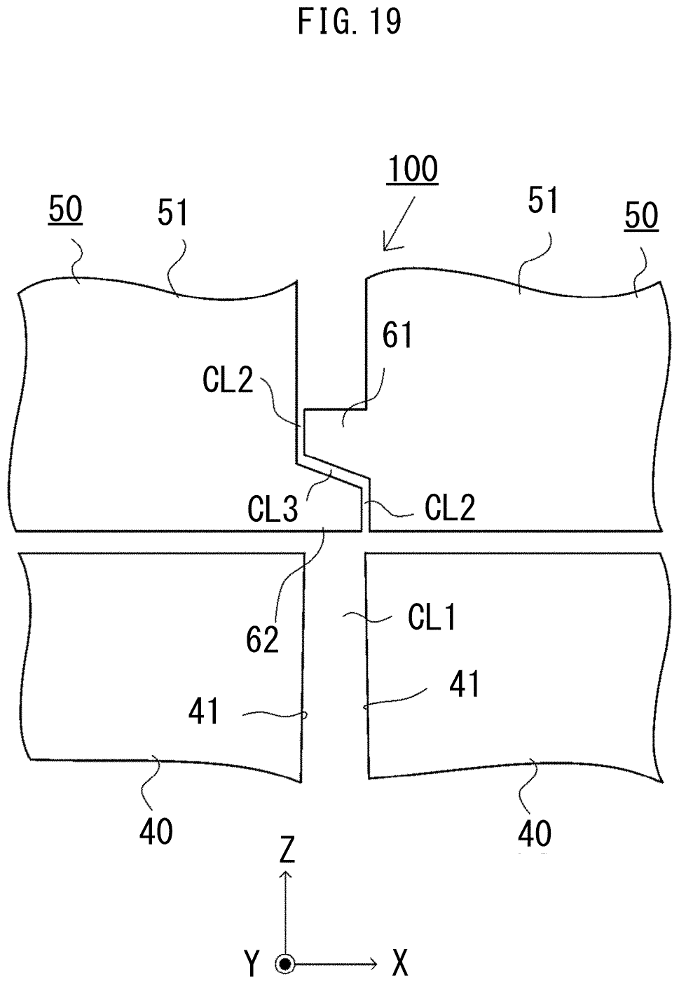

As illustrated in FIG. 19, the first extended portion 61 and the second extended portion 62 may be configured to have a tapered shape that narrows with increase in distance from the base end portion 51, and the first extended portion 61 and the second extended portion 62 may be arranged such that the first and second extended portions face each other in the Z-axis direction. In this case, the first extended portion 61 and the second extended portion 62 preferably face each other in the Z-axis direction with the gap CL3 therebetween.

The third extended portion 63 and the fourth extended portion 64 may be configured to have a tapered shape that narrows with increase in distance from the base end portion 51, and the third extended portion 63 and the fourth extended portion 64 may be arranged such that the third and fourth extended portions face each other in the Z-axis direction. In this case, the third extended portion 63 and the fourth extended portion 64 preferably face each other in the Z-axis direction with the gap CL3 therebetween.

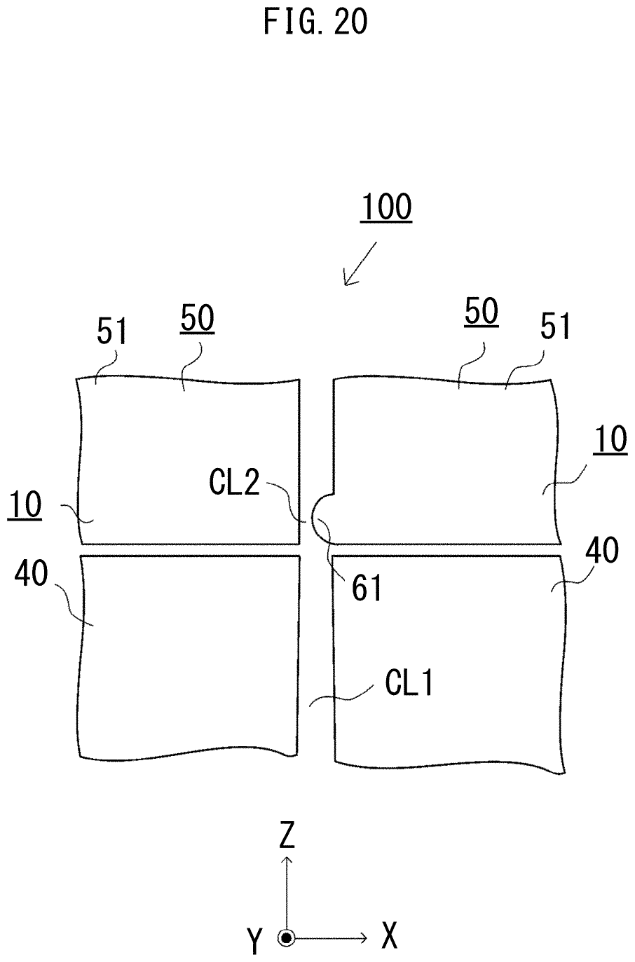

As illustrated in FIG. 20, the first extended portion 61 may be configured to have an arc shape. Although not illustrated, the second extended portion 62, the third extended portion 63, or the fourth extended portion 64 may be also configured to have an arc shape.

In Embodiment 1, the gap CL2 is provided between the first extended portion 61 and the base end portion 51 of the adjacent louver 50. However, the present disclosure is not limited to such configuration. For example, the first extended portion 61 and the base end portion 51 of the adjacent louver 50 may be arranged without providing the gap CL2 therebetween. That is, the first extended portion 61 and the base end portion 51 of the adjacent louver 50 may be arranged so as to come into contact with each other.

In each of Embodiments 2 to 4 and the modified examples described above, the gap CL2 between the second extended portion 62 and the base end portion 51 of the adjacent louver 50, between the third extended portion 63 and the base end portion 51 of the adjacent louver 50, or between the fourth extended portion 64 and the base end portion 51 of the adjacent louver 50 may be omitted. That is, the second extended portion 62 may be arranged so as to come into contact with the base end portion 51 of the adjacent louver 50. Similarly, the third extended portion 63 may be arranged so as to come into contact with the base end portion 51 of the adjacent louver 50. Similarly, the fourth extended portion 64 may be arranged so as to come into contact with the base end portion 51 of the adjacent louver 50.

In Embodiment 2, although the first extended portion 61 and the second expansion portion 62 are arranged spaced away from each other by the gap CL3, the present disclosure is not limited to such configuration. For example, the first extended portion 61 and the second extended portion 62 may be arranged without providing the gap CL3 therebetween. That is, the first extended portion 61 and the second extended portion 62 may be arranged so as to come into contact with each other.

In each of the above-described modified examples, although the third extended portion 63 and the fourth extended portion 64 are arranged to be spaced away from each other by the gap CL3, the present disclosure is not limited to such configuration. For example, the gap CL3 between the third extended portion 63 and the fourth extended portion 64 may be omitted. That is, the third extended portion 63 and the fourth extended portion 64 may be arranged so as to come into contact with each other.

The louver 50 may be configured to include all of the first extended portion 61, the second extended portion 62, the third extended portion 63, and the fourth extended portion 64.

The display device 100 may be composed of one display unit 10.

The gap CL2 or CL3 described in Embodiments 1 to 4 or the above-described modified examples may be filled with material such as a transparent resin. According to this modified example, intrusion of foreign matter into the display device 100 can be more advantageously suppressed. A water-repellant resin is preferably used as the transparent resin.

In Embodiments 1 to 4, although the case 40 is made of resin material such as a polycarbonate resin or an acrylic resin, the present disclosure is not limited to such configuration, and the case 40 may be made of a metal material such as an aluminum alloy, a magnesium alloy, or the like.

In Embodiments 1 to 4, although 3-in-1 surface-mount LED elements are used as the light emitting elements 30, the present disclosure is not limited to such configuration, and 1-in-1 type LED elements or through-hole type LED elements may be used as the light emitting elements 30.

The support frame 200 may be composed of only the column 220 by omitting the beam 210 in order to reduce wind load. Alternatively, the column 220 may be omitted and the support frame may include only the beam 210.

### REFERENCE SIGNS LIST

10 Display unit
20 Circuit board
22 Mounting surface
23 Filler
30 Light emitting element
40 Case
41 Outer surface
42 Opening
45 Bottom
46 Side wall
47 Inner surface
50 Louver
51 Base end portion
52 Eaves portion
54 Opening
61 First extended portion
62 Second extended portion
63 Third extended portion
64 Fourth extended portion
100 Display device
200 Support frame
210 Beam
220 Column

1. A display unit comprising:
a case having an opening;
a circuit board disposed in the case;
light emitting elements mounted on the circuit board; and
a reflection suppressing member comprising
a base end portion that covers the opening of the case, and
an extended portion arranged at the base end portion,
wherein the extended portion extends more outward than an outer surface of the case.

2. The display unit according to claim 1, wherein
the reflection suppressing member comprises a plurality of the extended portions, and
the extended portions are disposed on two sides of the base end portion that are opposite to each other and the extended portions are different from one another in position in a thickness direction of the base end portion.

3. A display device comprising the display unit according to claim 1.

4. A display device comprising:
the display unit according to claim 1,
wherein the display unit is arranged such that at least a portion of the extended portion is located vertically above or vertically below the base end portion.

5. A display device comprising:
a plurality of the display units according to claim 2 in combination,
wherein a pair of display units, among the plurality of display units, that are adjacent to each other are arranged such that the extended portion included in one of the pair of display units faces, in the thickness direction of the base end portion, the extended portion included in another one of the pair of display units.

6. The display device according to claim 5, wherein the extended portion included in the one of the pair of display units faces, in the thickness direction of the base end portion, the extended portion included in the another one of the pair of display units with a gap therebetween.

7. A display device comprising the display unit according to claim 2.

8. A display device comprising:
the display unit according to claim 2,
wherein the display unit is arranged such that at least a portion of each extended portion is located vertically above or vertically below the base end portion.
